(19) United States
(12) Patent Application Publication
(10) Pub. No.: US 2025/0081628 A1
(43) Pub. Date: Mar. 6, 2025

(54) Silicon Substrate with ESD Protection Element

(71) Applicant: TDK Electronics AG, Munich (DE)

(72) Inventors: Thomas Feichtinger, Graz (AT); Stefan Endler, Graz (AT)

(21) Appl. No.: 18/251,516

(22) PCT Filed: Nov. 15, 2021
(86) PCT No.: PCT/EP2021/081681

§ 371 Date: May 2, 2023

(30) Foreign Application Priority Data
Nov. 16, 2020 (DE) 10 2020 130 194.4

(51) Int. Cl. H01L 27/02; H01L 23/60

(52) U.S. Cl. CPC H10D 89/921; H01L 23/60; H10D 89/611; H10D 89/713; H10D 89/931

(57) ABSTRACT

In an embodiment a silicon substrate includes integrated circuits located on a first surface, a second surface opposite to the first surface, a first via and an ESD protection element, wherein the ESD protection element is fully integrated into the silicon substrate, wherein the ESD protection element is spatially distant from the first via, wherein the ESD protection element is connected to the via by a first rewiring, and wherein the ESD protection element comprises a suppressor diode, a transistor or a thyristor.

### CROSS-REFERENCE TO RELATED APPLICATIONS

This application is a national state of International Application No. PCT/EP2021/081681, filed on Nov. 15, 2021, which claims priority to DE 102020130194.4, filed Nov. 16, 2020. The aforementioned applications are hereby incorporated by reference in their entireties.

### TECHNICAL FIELD

The invention relates to a silicon substrate with ESD protection element.

### BACKGROUND

Application Specific Integrated Circuits (“ASIC”) are used in electronic System in a Package (“SIP”) modules or for example in MEMS microphones or other modules suitable for mobile application. These integrated circuits are usually protected by on-chip ESD (overvoltage) protection structures. In the present application, on-chip ESD protection structures are understood to be those ESD protection structures which are a direct part of an integrated circuit chip, which can usually be placed on a substrate. An example of such an on-chip ESD protection structure is shown in FIG. 7, which represents prior art. As shown in FIG. 6, an ASIC 50 may be disposed on a substrate 1′, which itself is again disposed on a printed circuit board 52. On-chip ESD protection structures (2′) may occupy more than one-third of the available chip area or substrate area. This is contrary to the requirement that present and future applications must be increasingly miniaturized in their lateral size.

So far, no concepts are known in which ESD protection structures can be clearly separated from other structures and flexibly integrated into a substrate in terms of size. Previous systems in which ESD structures are located in the substrate are severely limited in their application possibilities and have various disadvantages.

In U.S. Pat. No. 8,164,113 B2, diode structures are described as ESD protection at vias through a silicon substrate (“through silicon vias”). The diodes are obtained by suitable doping of the silicon substrate in the immediate vicinity of the vias.

However, this direct coupling does not allow more complex ESD protection structures, which may include transistors or thyristors, for example, to be implemented in the substrate.

U.S. Pat. No. 9,412,708 B2 describes a further arrangement of ESD protection elements, which are arranged in an intermediate piece (“interposer”) on a printed circuit board (“PCB”). It is described here that the ESD protection elements can be connected via vias within the interposer.

US 2015/0048497 A1 shows simple ESD protection structures for silicon solar cells, which are based on simple diode systems and can be connected to vias in the substrate via rewiring-like structures.

US 2008/0296697 A1 describes that ESD protection structures, which in this case can include transistors as well as simple diodes, can be implemented near an interface in a silicon substrate.

When vias are realized in silicon substrates, the sidewalls of the openings created in the silicon substrate are usually passivated. US 2020/0161244 A1 describes ways to create such a passivation.

DE 10 2018 118 016 A1 discloses only in general terms that overvoltage protection structures (ESD protection structures) can be integrated into ceramic substrates, in particular varistor substrates.

US 2011/0079912 A1 discloses a stacked structure with integrated ESD protection.

WO 2017/091155 A1 discloses an integrated circuit with a thyristor as an ESD protection element.

US 2013/0240922 A1 discloses a light emitting element in which feedthroughs as well as a pn diode can be implemented.

### SUMMARY

Embodiments provide a silicon substrate. Integrated circuits are disposed on a first surface of the silicon substrate. The substrate further comprises a first via and an ESD protection element. Here, it is preferred that the first via penetrates the silicon substrate from the first surface to a second surface. The second surface is opposite the first surface. Furthermore, the ESD protection element is integrated into the silicon substrate. That is, the ESD protection element is recessed in the silicon substrate, i.e., it is located entirely within the volume of the substrate. In addition, the ESD protection element is spatially spaced from the first via. The spacing preferably exists along the extension direction of the silicon substrate, for example a direction parallel to the first surface. Furthermore, the ESD protection element is connected to the vias by means of a first rewiring. Further, the ESD protection element comprises at least one selected from the following group consisting of a suppressor diode, a transistor, and a thyristor.

The silicon substrate can be any type of substrate made of silicon, for example amorphous or polycrystalline silicon. Preferably, however, the silicon substrate is a wafer, such as a single-crystal silicon wafer.

Embodiments provide an off-chip ESD structure that can be tailor-made to integrated circuit elements, such as application specific integrated circuits (ASICs). These integrated circuit elements are here preferably located on or above the first surface of the silicon substrate. In contrast to the on-chip ESD structure, the off-chip ESD structure is not located on the chip to be protected itself, but is embedded separately in the silicon substrate. Thus, it is possible to reduce the chip size since the off-chip ESD protection does not have to be part of the chip.

In particular, the ESD protection elements can be system level ESD protection or the ESD protection element can provide system level ESD protection. This means that all integrated circuits are protected together, and not just a single circuit or part of a circuit. The ESD protection at system level can, for example, be an input signal-to-output signal protection, i.e. an ESD protection that systemically protects all electronic components or integrated circuits that are installed between an input signal line and an output signal line against overvoltages.

In addition to the system-level ESD protection provided by the ESD protection element, further ESD protection structures can be implemented in application-specific integrated circuits. These further ESD protection structures here can be, for example, on-chip protection structures. Here it is advantageous to provide a tailored matching between the ESD protection element and the further ESD protection structure in the application specific integrated circuit. Thus, it is a further embodiment to provide a tailored matching of the one off-chip ESD protection element and an on-chip protection element.

The spacing of the ESD protection element from the via and the connection via rewiring is very advantageous, as this allows both the impedances of the ESD protection structures and the stop time of the ESD protection element to be influenced, and can thus be adjusted to suit the application in question.

As a further aspect, the ESD protection element may additionally comprise EMI protection structures (Electromagnetic Interference protection structures). It is advantageous to implement electromagnetic interference protection (EMI protection) directly together with the ESD protection. In the case of high-frequency data lines in particular, both the ESD protection requirements and the resulting capacitances and inductances or parasitic capacitances must be tailored in parallel.

In this context, the EMI protection structures are formed by coil structures, thin-film resistors and/or capacitors. That is, either coil structures, thin-film resistors or capacitors can be used, or any combination of such elements.

The selection of these elements is tailored to the specific application.

According to a further aspect, the silicon substrate may comprise an ESD protection element constructed from a structure embedded in the silicon substrate comprising a combination of a thyristor with diode structures. Diode structures here can be semiconductor structures with diode function. The diode structures are not part of the thyristor structures here.

In on-chip ESD protection devices, the combination of thyristors and diode structures is already common. However, these components can now be recessed or integrated into the silicon substrate, thus providing off-chip ESD protection.

Preferably, a passivation layer is also formed on the first surface of the silicon substrate. Furthermore, it is advantageous that the ESD protection element is in direct contact with the first surface on which the passivation layer is located. That is, the ESD protection element is thus preferably in contact with the passivation layer directly on this first surface.

According to a further aspect, the silicon substrate may comprise at least one additional rewiring. In this regard, the additional rewiring may electrically connect the first via to an under-bump metallization (UBM) contact pad. For example, in such a case, the rewiring may run in the previously described passivation layer. Then, preferably, the UBM contact pad is arranged on or in the surface of the passivation layer in such a way that it is suitable for contacting further electronic elements, for example via solder bumps. It is particularly preferred here that the additional rewiring (7) can comprise adjustment elements. These adjustment elements include capacitors, inductors or delay elements. These can thus serve to match the impedances of the integrated ESD protection element to the additional electronic components such as ASICs, which is connected to the UBM contact pad connected in this way. In addition, the impact time can be adjusted in the event of an ESD event.

This optional additional rewiring is preferably different from the first rewiring.

According to a further aspect, the silicon substrate additionally comprises a second via that penetrates the silicon substrate from the first surface to the second surface. Further, in this silicon substrate, the ESD protection element is also spatially spaced from the second via, similar to the first via. Further, in this case, the ESD protection element is connected to the second via by a second rewiring. The connection described here consisting of the ESD protection element, the first and second via and the first and second rewiring is referred to here and in the following as an ESD circuit.

For example, the ESD circuit can be symmetrical, i.e., the ESD protection element can be arranged symmetrically between two rewirings and vias. The first and second rewirings and the first and second vias can be very similar or identical to each other.

According to a further aspect, there is disclosed a silicon substrate comprising a plurality of the ESD circuits as described above. In this regard, a plurality of ESD circuits are formed side-by-side in a common silicon substrate. That is, a plurality of ESD protection elements may be included in the silicon substrate, each of which is connected to a first and a second via with a first and a second rewiring, respectively.

According to a further aspect, the silicon substrate described above can be used for a micromechanical system microphone (MEMS). That is, the MEMS microphone may be constructed on a silicon substrate as described above.

Further embodiments provide a method for making an ESD protective element in a silicon substrate as described in the foregoing.

Here, embedded structures of an ESD protection element are first fabricated in the silicon substrate using a CMOS (complementary metal-oxide-semiconductor) process. The embedded structures of the ESD protection element have at least one selected from the following group consisting of a suppressor diode, a transistor, and a thyristor. After forming the ESD protection element structures, first contact pads are formed on one of the surfaces of the silicon substrate.

Openings are then created in the silicon substrate for vias between a first surface and a second surface of the silicon substrate. The openings can be created by laser or deep reactive ion etching (DRIE). The openings are formed such that they are spatially spaced, in particular, from the embedded structures of the ESD protection element. The spacing is aligned in the direction of extension of the silicon substrate.

The inner walls of the openings are then passivated. Then the openings are filled with a first metal to create vias. Furthermore, rewirings of a second metal are created between the vias and the integrated circuits of the ESD protection element. In other words, the rewirings electrically connect the vias to the ESD protection element.

The method described herein can be used to fabricate an ESD protective element as described above, or a substrate as described above.

This means that integrated circuits, such as ASICs, can be created or arranged on the first surface of the silicon substrate in a later step of the manufacturing process.

For example, according to the above example, these integrated circuits can be parts of a MEMS microphone, such as the control electronics.

According to another aspect of the method of making an ESD protection element in a silicon substrate, the first metal may be copper (Cu). In this case, the vias can be made by filling the openings by means of galvanic processes.

Furthermore, the rewiring can be made of aluminum (Al) or Cu.

Furthermore, the passivation of the inner walls of the openings can be passivated prior to the formation of the vias, i.e. prior to filling with a first metal, for example via Atomic Layer Deposition (ALD process) or via plasma etch process (successive dry etching and passivation). This passivation via the plasma etching process can be done during a DRIE etch. Accordingly, the plasma etching process can be part of a DRIE process.

According to another aspect of the method, in a further step, preferably before integrated circuits such as ASICs are generated on or above the first surface, passivation can be generated on the first surface and also on the second surface.

The passivation provided here corresponds to the passivation as described above for the substrate. It may, for example, comprise or consist of silicon oxide, but preferably polymer-based passivation layers.

UBM contact pads are implemented in or on the corresponding passivation layers, which can be in contact with the elements of an integrated circuit above the first surface. In the case of thinner passivation layers, UBM contact pads can extend through the passivation layer in the thickness direction and thus enable direct electrical contact with the vias. However, the UBM contact pads can also be in indirect contact with the vias. In the case of thick passivation layers, additional rewiring can be made to indirectly connect the UBM contact pads to the vias, as described above.

### BRIEF DESCRIPTION OF THE DRAWINGS

The invention is described in more detail below with reference to exemplary embodiments. These exemplary embodiments are shown in the following figures, which are not to scale. Dimensions as well as relative and absolute dimensions can thus not be taken from the figures. The invention is also not limited to the following embodiments.

FIG. 1 shows a first embodiment of a silicon substrate in schematic cross-section;

FIG. 2 shows a second embodiment of a silicon substrate in schematic cross-section;

FIG. 3 shows a third embodiment of a silicon substrate in schematic cross-section;

FIG. 4 shows a fourth embodiment of a silicon substrate in schematic cross-section;

FIG. 5 shows a MEMS microphone in schematic cross-section;

FIG. 6 shows a schematic cross-section of an ASIC on a substrate according to the invention on a printed circuit board; and

FIG. 7 shows a schematic cross-section of an ASIC on a prior art substrate on a printed circuit board prior to the present invention.

### DETAILED DESCRIPTION OF ILLUSTRATIVE EMBODIMENTS

FIG. 1 shows a first embodiment of a silicon substrate 1 according to the present invention and is shown in schematic cross-section.

The silicon substrate 1 here is a silicon wafer. However, in principle, any other silicon substrate is also suitable as silicon substrate 1. The silicon substrate 1 has a first surface 11 and, opposite this, a second surface 12. Preferably, the second surface 12 is oriented parallel to the first surface. Here, the direction of extension of the silicon substrate 1 is the direction parallel to the first surface 11.

An ESD protection element 2 is recessed into the silicon substrate 1. In the present embodiment example, the ESD protection element 2 is in direct contact with the first surface 11 of the silicon substrate 1. Furthermore, the ESD protection element 2 is fully recessed into the silicon substrate 1.

The ESD protection element 2 is spaced from a first via 3. This means that the ESD protection element 2 and the first via 3 usually have a distance greater than 0 in the direction in which the silicon substrate 1 extends, i.e. they are spatially separated or spaced apart from one another.

The specific design of the ESD protective element 2 also depends on the target application and can be tailored to this. In particular, a low clamping voltage should be achieved. The embedded structure of the ESD protection element 2 is at least one TVS diode (suppressor diode), which is embedded in the silicon substrate. Besides or alternatively a transistor or thyristor can be used. For many applications, the preferred embedded structure of the ESD protection element 2 is an integrated circuit consisting of the combination of thyristor and diode structures. Depending on the application, the extent of the ESD protection element 2 in the plane of the direction of extension may be between 50 m×50 m and 300 m×300 m, and the shape here may be, but is not limited to, a rectangle. The substrate may also be circular in the plane of the direction of extension. The size is based on the voltage of an ESD event to protect against. For common ESD protection against voltage spikes of 8 kV to 30 kV, extensions of the ESD protection element 2 in the direction of extension of 100 m×100 m to 200 m×200 m are preferred, although again the shape is not limited.

Furthermore, the ESD protection element 2 can still be provided with electromagnetic interference protection structures (EMI protection structures). Coils structures, thin film resistors and/or capacitors can serve as such. Capacitances in particular, however, are already inherently introduced by the embedded structure of the ESD protection element. Thus, these have to be adapted to the application. This plays a particularly important role in the case of high-frequency data lines.

The first via 3 is a through silicon via (TSV) and extends between the first surface 11 and the second surface 12. Preferably, the first via 3 is made of a conductive metal (first metal), such as copper.

As shown in FIG. 1, the first via 3 can be tapered, and for example be thicker on the side of the first surface 11 and thinner on the side of the second surface 12. Alternatively, the taper may be in the opposite direction, and thus be thinner on the side of the first surface 11 and thicker on the side of the second surface 12. Further, the thickness may also be substantially uniform. In principle, the shape may depend on the manufacturing process used, as also explained below. For example, by laser cutting from the side of the first surface, the taper as shown in FIG. 1 can be achieved. By laser cutting from the side of the second surface, an inverse conicity can be achieved. If a DRIE process is used, the result is a shape for the first via 3 that is largely cylindrical, but can have, for example, the indentations typical of DRIE.

The interface between the conductive metal of the first via 3 is preferably passivated with an insulation layer 30, i.e. electrically insulated. The insulation layer 30 is usually formed along the entire interface between the first via 3 and the silicon substrate 1.

The electrical or electronic connection between the ESD protection element 2 and the first via 3 is made via a first rewiring 4, which can run along the first surface 11, for example. Here, the first rewiring 4 can be slightly embedded in the first surface 3, or run on it. The first rewiring 4 can be made of any conductive metal (second metal), such as aluminum or copper.

In combination with the distance between ESD protection element 2 and first via 3 described above, the impedance of the circuit and the response time of the ESD protection can be influenced via the first rewiring 4.

A first passivation 5 and a second passivation 5′, i.e. an electrically insulating and largely inert layer, are arranged on the first surface 11 and on the second surface 12, respectively. In principle, this can be made of any material that fulfills these conditions. In the present embodiment, it consists of polymer passivation layers.

In addition, UBM contact pads 6 and 6′ are provided on the first surface 11 and on the second surface 12. These are arranged directly above and below the first via 3 and can, for example, be made of the same material as the first via 3 or the first rewiring 4. However, the UBM contact pads 6 and 6′ may further be made of or comprise the following metals comprising aluminum, titanium, copper, nickel, palladium, silver, gold, or tin. For example, one of these metals may form the main volume of the UBM contact pad 6 or 6′, and one or more of the other metals may form the surface of the UBM contact pad 6 or 6′ as a thin layer. The contact pads 6 and 6′ extend through the upper passivation layer 5 and the lower passivation layer 5′, respectively. They serve as contact pads, e.g. for attaching integrated circuits above the first surface via soldering, or for providing external contact, such as for an input signal. I.e., in the case of an application, if integrated circuits, such as ASICs, are located directly on or above the silicon substrate, they can be electrically connected via solder bumps to the UBM contact area 6 and thus to the rewiring 4.

The first via 3 and the UBM contact pads 6 and 6′ connected thereto may, for example, form the signal line of a connected electronic component, such as an ASIC.

Another second UBM contact pad 62, arbitrarily attached to the silicon substrate, may serve as a ground. This can be manufactured in a similar way to the UBM contact pad 6 and is connected to a grounded line in any way.

In principle, the components are manufactured by any suitable process. Preferably, the following process is used. The silicon substrate 1 is provided on a carrier film. The embedded structures of the ESD protection element 2, including the EMI protection structures can be introduced into the silicon substrate using a CMOS process. Then, a the passivation layer 5 can be formed on the first surface 11 together with the first rewiring layer 7. Then, the UBM contact pad 6 and the second UBM contact pad 62 are formed on the first surface 11 of the silicon substrate 1, e.g., of Cu using photolithographic processes. Subsequently, openings for the first via 3 are created between the first surface 11 and a second surface 12 of the silicon substrate 1 by laser or DRIE. When lasered from the side of the second surface, the first via 3 may have an inverted taper to that of FIG. 1. The inner walls of the openings are passivated by either an ALD process or a plasma etching process, which creates the insulation layer 30 of the first via 3. The plasma etching process may be part of the DRIE process. Subsequently, the openings are filled with the first metal, i.e. the metal of the via 3, by an electroplating process. Subsequently, the silicon substrate can be thinly ground from the side of the second surface and then the second passivation layer 5′ can be applied. Furthermore, photolithographic patterning is used to form the UBM contact pad 6′ on the second surface 12. This can also be provided with gold or nickel layers via electrochemical deposition. The silicon substrate 1 can now be sawn to the correct shape and size using a plasma sawing process, for example. The silicon substrate processed in this way can be removed from the carrier film.

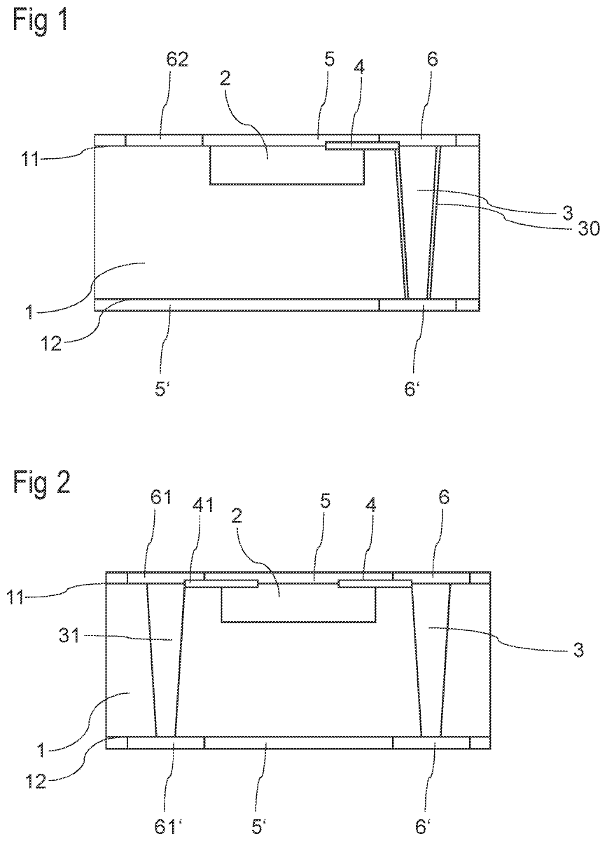

FIG. 2 shows a second embodiment of a silicon substrate 1 in schematic cross-section.

The silicon substrate 1 largely corresponds to the silicon substrate 1 as described in connection with FIG. 1. It can also be manufactured in the same way. It should be noted here that an insulation layer of the first via 3 is not explicitly shown, but is preferably formed.

In addition to the components shown in FIG. 1, the silicon substrate 1 of the second embodiment has a second via 31. This is preferably manufactured similarly to the first via 3. On this second via 31, contact pads 61 and 61′ are also arranged on the first surface 11 and on the second surface 12, respectively, similar to the contact pads 6 and 6′ on the first via 3. In particular, the contact pad 61 of the second via 31 can replace the contact pad 62 as shown in FIG. 1.

The ESD protection element 2 is also spaced from the second vias 31, similarly as it is spaced from the first vias 3.

The second vias 31 are connected to the ESD protection element 2 via a second rewiring 41. The second rewiring 41 is preferably manufactured in accordance with the first rewiring 4.

In one application, either the first vias 3 or the second vias 31 is preferably a signal line, e.g. for an input or output signal. The other vias are then preferably connected to ground. Thus, the signal line can be protected against this ground via by the ESD protection element.

The combination of ESD protection element 2, first vias 3, first rewiring 4, second vias 31, and second rewiring 41 is defined as an ESD circuit.

The silicon substrate 1 shown in FIG. 2 is also suitable as an intermediate piece, also called an interposer, on whose surface ASICs, for example, can be arranged.

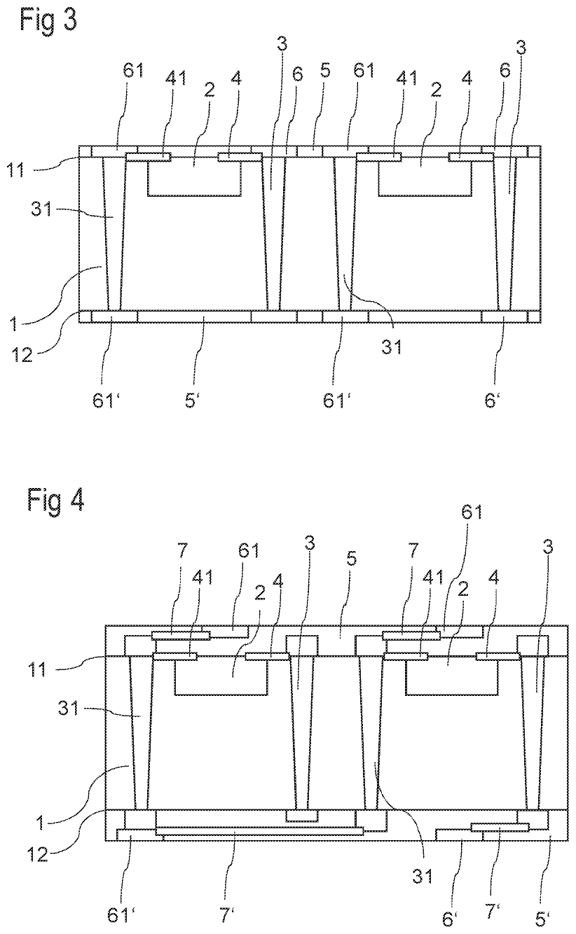

FIG. 3 shows a third embodiment example of a silicon substrate 1 in schematic cross-section. The third embodiment of a silicon substrate 1 comprises of two ESD circuits as defined to FIG. 2. These are integrated into the common silicon substrate 1. The structures can thus correspond to each other to a large extent. In principle, however, the two ESD protection elements 2 in particular can be different, since they protect different electronic components with different ESD protection requirements.

In such a design, however, ESD protection of a single component can be provided by one of the two ESD protection elements 2, and system-level ESD protection can be provided by the other ESD protection element 2.

Similarly, it is possible to implement any plurality of ESD protection elements 2 in a substrate, i.e., to integrate a plurality of ESD circuits in a substrate.

FIG. 4 shows a fourth embodiment of the silicon substrate 1, where all structures within the silicon substrate 1 correspond to those from the first embodiment of the module as shown in FIG. 3.

In contrast to the first module shown in FIG. 3, however, in the second module additional rewirings 7 or 7′ are embedded in the first or second passivation layer 5 or 5′, respectively.

The additional rewirings 7 in the first passivation layer 5 each connect one of the two second vias 31 to a UBM contact pad 61, which is located on the outside (top) of the first passivation layer 5.

One or both of the additional rewirings 7, but in particular the additional rewiring 7 which is grounded, may comprise adjustment elements. These may comprise capacitors, inductors or delay elements. That is, coils or capacitors, for example, may be part of the additional rewiring 7. The delay is determined in particular by the length of the additional rewiring 7. That is, delay elements can be elements that increase the line length of the additional rewiring 7 and can thus delay any ESD pulse.

In the second passivation layer 5′ on the underside of the substrate, an additional rewiring 7′ connects one of the second vias 31 to a UBM contact pad 61′ which is arranged directly on the other second via 31, similar to the UBM contact pads in the preceding examples.

Another additional rewiring 7′ in the second passivation layer 5′ connects one of the first vias 3 to another UBM contact pad 6′.

Similar to the preceding example, for example, either the first or the second vias may be grounded and the other two vias may each form a signal line or be connected to a signal line.

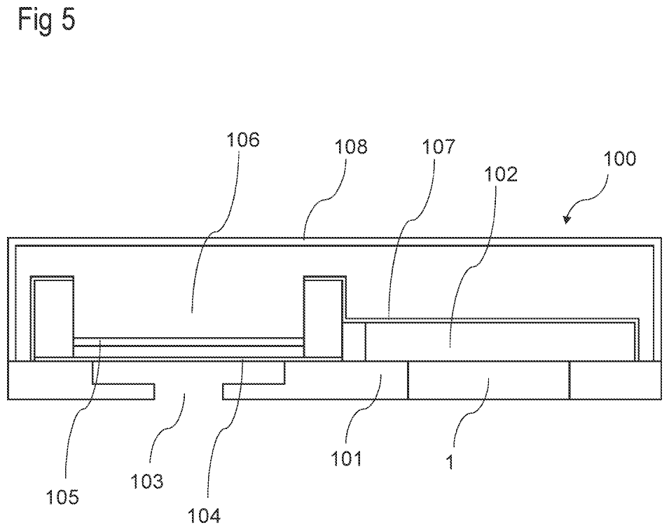

FIG. 5 shows a MEMS microphone 100 as one possible application example of the invention.

The MEMS microphone 100 includes the substrate 101. The substrate 101 may correspond to the silicon substrate 1 as described with respect to previously shown FIGS. 1-5, or the silicon substrate 1 may be part of the substrate 101. That is, for example, one or more ESD circuits, such as those described with respect to FIG. 2, are present in the region marked here as the silicon substrate 1.

The one or more ESD protection elements included in the ESD circuits protect components and/or provide system-level ESD protection for an ASIC 102 of the MEMS microphone 100 disposed on or above the substrate 101.

ASIC 102 may, for example, be electronically connected via solder bumps to UBM contact pads (not shown) or to vias connected thereto, as described in the preceding examples.

Other components of the MEMS microphone include, for example, the sound opening 103 in the substrate 101, the diaphragm 104, the back plate (static capacitor plate) 105, and the rear chamber 106 that forms the back volume of the MEMS microphone.

Preferably, a polymeric film wrap 107 is applied to the components. The wrapping 107 is different from the passivation layers as described for FIG. 1. The MEMS components can be sealed, for example, by a metal cover 108.

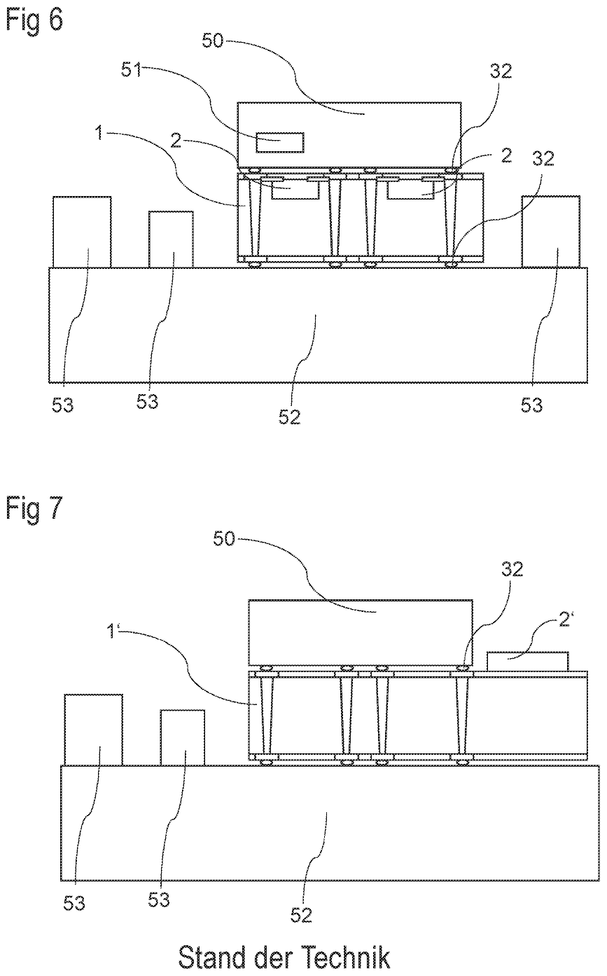

Another application of the substrate 1 according to the invention is shown in FIG. 6.

FIG. 6 shows a printed circuit board (PCB) 52 on which several electronic components 53 are arranged.

In addition, the silicon substrate 1 according to the invention, here in the function of an interposer, is attached to the printed circuit board 52. The silicon substrate 1 may correspond to that shown in FIG. 3, but alternatively may also correspond to the other embodiments described herein.

In particular, multiple ESD protection elements 2 are integrated into the silicon substrate 1.

An ASIC 50 is mounted on the silicon substrate 1. This ASIC 50 has, for example, its own additional ESD protection structures 51. These are preferably individual protective structures of one or more components of the ASIC.

Thus, coordinated therewith, one of the ESD protection elements 1 can provide system-level ESD protection.

The connection between the different components can be made by solder bumps 32, which are placed on the UBM contact pads.

FIG. 7 shows an ESD protection configuration on a printed circuit board 52 according to prior art before the present invention.

The ESD protection element 2′ not according to the invention is here arranged in on-board configuration on a substrate 1′ not according to the invention. The ESD protection element 2′ thus takes up additional space next to the structures to be protected (ASIC 50).

This can reduce the number of components on the printed circuit board, i.e., the integration density, as can be seen by comparison with the embodiment of the invention in FIG. 6. In other words, the present invention enables a higher integration density.

### LIST OF REFERENCE SIGNS

1 Silicon substrate
1′ Substrate not according to the invention
2 ESD protection element
2′ On-board ESD protection element not according to the invention
3 first via
4 first rewiring
first passivation layer
5′ second passivation layer
6, 6′ UBM contact pads of the first via
7, 7′ additional rewiring
11 first surface
12 second surface
30 Insulation layer of the first rewiring
31 second via
32 solder bump
41 second rewiring
50 ASIC
51 ESD protection structures of the ASIC
52 Printed circuit board
61, 61′ UBM contact pads of the second via
62 second UBM contact pad
100 MEMS microphone
101 substrate of the MEMS microphone
102 ASIC of the MEMS microphone
103 sound opening
104 diaphragm
105 back plate
106 rear chamber
107 film wrap
108 metal cover

1-16. (canceled)

17. A silicon substrate comprising:
integrated circuits located on a first surface;
a second surface opposite to the first surface;
a first via; and
an ESD protection element,
wherein the ESD protection element is fully integrated into the silicon substrate,
wherein the ESD protection element is spatially distant from the first via,
wherein the ESD protection element is connected to the first via by a first rewiring, and
wherein the ESD protection element comprises a suppressor diode, a transistor or a thyristor.

18. The silicon substrate according to claim 17, wherein the ESD protection element is configured to provide system-level ESD protection.

19. The silicon substrate according to claim 18, wherein several electronic components or the integrated circuits have an individual ESD protection arranged in an on-chip structure in addition to the system-level ESD protection.

20. The silicon substrate according to claim 17, wherein the ESD protection element is configured to provide system-level input-to-output signal protection for a plurality of electronic components and the integrated circuits.

21. The silicon substrate according to claim 17, wherein the ESD protection element additionally comprises EMI protection structures.

22. The silicon substrate according to claim 21, wherein the EMI protection structures comprise coil structures, thin film resistors and/or capacitors.

23. The silicon substrate according to claim 17, wherein the ESD protection element comprises embedded structures from a combination of the thyristor and the diode structures which are not part of the thyristor.

24. The silicon substrate according to claim 17, wherein the ESD protection element is in contact with a first passivation layer arranged on the first surface of the silicon substrate.

25. The silicon substrate according to claim 17, further comprising:
at least one additional rewiring,
wherein the additional rewiring electrically connects the first via to a UBM contact pad,
wherein the additional rewiring comprises adjustment elements, and
wherein the adjustment elements comprise capacitors, inductors or delay elements.

26. The silicon substrate according to claim 17, further comprising:
a second via penetrating the silicon substrate from the first surface to the second surface,
wherein the ESD protection element is spatially separated from the second via,
wherein the ESD protection element is connected to the second via via a second rewiring, and
wherein the ESD protection element forms an ESD circuit via the first via, the first rewiring, the second via and the second rewiring.

27. The silicon substrate comprising:
a plurality of ESD circuits, each ESD circuit being the ESD circuit according to claim 26.

28. The silicon substrate according to claim 17, wherein the first via is insulated from the silicon substrate by an insulation layer.

29. The silicon substrate according to claim 17, wherein the integrated circuits or electronic components comprise a MEMS microphone.

30. A method for manufacturing an ESD protection element in a silicon substrate, the method comprising:
forming, by a CMOS process, embedded structures of the ESD protection element in the silicon substrate, wherein the embedded structures of the ESD protection element comprise a suppressor diode, a transistor or a thyristor;
forming first UBM contact pads on a first surface of the silicon substrate;
producing, by a laser or reactive ion deep etching, openings for vias between the first surface and a second surface in the silicon substrate, wherein the openings are spatially separated from the embedded structures of the ESD protective element;
passivating interior walls of the openings;
filling the passivating openings with a first metal thereby creating the vias;
forming rewirings from a second metal between the vias and the embedded structures of the ESD protection element.

31. The method according to claim 30,
wherein the first metal is Cu,
wherein the vias are produced by filling the openings by a galvanic process,
wherein the second metal is Cu or Al.

32. The method according to claim 30, further comprising forming passivation layers on the first surface and on the second surface.
